(19) United States
(12) Patent Application Publication
(10) Pub. No.: US 2022/0102338 A1
(43) Pub. Date: Mar. 31, 2022

(54) ELECTROSTATIC PROTECTION ELEMENT AND SEMICONDUCTOR DEVICE

(71) Applicant: LAPIS Semiconductor Co., Ltd., Yokohama (JP)

(72) Inventors: Masahiko HIGASHI, Yokohama (JP); Marie MOCHIZUKI, Yokohama (JP)

(73) Assignee: LAPIS Semiconductor Co., Ltd., Yokohama (JP)

(21) Appl. No.: 17/478,054

(22) Filed: Sep. 17, 2021

(30) Foreign Application Priority Data
Sep. 30, 2020 (JP) 2020-164726

(51) Int. Cl. H01L 27/02

(52) U.S. Cl. CPC H01L 27/0274

(57) ABSTRACT

A high-density source region is formed along a surface of a semiconductor substrate and is connected to either one of a power source line and ground line. A low-density source region has an exposed surface at a surface of the semiconductor substrate and is in contact with the high-density source region. A high-density drain region is formed along the surface of the semiconductor substrate and is connected to the other one of the power source line and the ground line. A low-density drain region has an exposed surface at the surface of the semiconductor substrate, is in contact with the high-density drain region, and extends to a deeper region from the surface of the semiconductor substrate than does the low-density source region. A gate electrode is connected to either one of the power source line and the ground line.

### CROSS REFERENCE TO RELATED APPLICATION

This application is based upon and claims the benefit of priority of the prior Japanese Patent Application No. 2020-164726, filed on Sep. 30, 2020, the entire contents of which are incorporated herein by reference.

### TECHNICAL FIELD

The present invention relates to an electrostatic protection element and a semiconductor device including the electrostatic protection element.

### BACKGROUND ART

Semiconductor IC chips, which are semiconductor devices, are provided with an ESD protection circuit that prevents a large current resulting from electrostatic discharge (hereinafter referred to as ESD) that occurs outside of the chip from flowing into an internal circuit via a power source terminal.

The ESD protection circuit includes an ESD protection transistor that connects a power source line to a ground line if the voltage of the power source line reaches a high voltage greater than or equal to a prescribed voltage. In order to protect the internal circuit, the ESD protection circuit relies on snapback in which, when a high voltage resulting from ESD is applied to the power source line via an external terminal, the ESD protection transistor operates, causing a current resulting from the high voltage to flow into the ESD protection transistor, and the voltage on the transistor to decrease and then be maintained at a given voltage (referred to as the hold voltage) (e.g., see Japanese Patent Application Laid-Open Publication No. 2016-162844).

### SUMMARY OF THE INVENTION

However, if the current flowing into the ESD protection transistor becomes excessively high, this can result in the Kirk effect. When the Kirk effect occurs, a depletion layer is formed and the current density of the current path increases. If a high voltage continues to be applied in this state, a larger current flows in between the collector and the emitter compared to a case in which the Kirk effect is not occurring, which reduces the hold voltage. If, at this time, a higher power source voltage than the hold voltage is applied to the power source line, the ESD protection transistor continues to operate even after ESD has ended. Thus, there was the risk that a current based on the power source voltage would continually flow into the ESD protection transistor, resulting in insufficient power supply to the internal circuit, or damage to the ESD protection transistor itself.

In order to alleviate this flaw, the electrostatic protection circuit disclosed in Japanese Patent Application Laid-Open Publication No. 2016-162844 adopts a configuration in which two ESD protection transistors are in a cascade connection between the power source line and the ground line. In the electrostatic protection circuit, the sum of the hold voltages occurring respectively in the two ESD protection transistors in the cascade connection is the hold voltage of the overall circuit. Thus, it is possible to set the hold voltage of the circuit to a greater voltage than the power source voltage, and thus, it is possible to suppress the current flowing into the ESD protection transistor even when the power source voltage is being applied after the end of ESD.

However, the configuration disclosed in Japanese Patent Application Laid-Open Publication No. 2016-162844 poses the problem that because two ESD protection transistors are necessary in order to prevent damage to the ESD protection transistors along with the internal circuit, the circuit area taken up within the semiconductor device is increased.

An object of the present invention is to provide an electrostatic protection element and a semiconductor device by which it is possible to prevent damage from electrostatic discharge to the internal circuit as well as the electrostatic protection element without resulting in an increase in circuit area or insufficient power supply to the internal circuit.

An electrostatic protection element according to the present invention includes: a semiconductor substrate of a first conductivity type; a high-density source region of a second conductivity type that is formed along a surface of the semiconductor substrate, and that is connected to either one of a power source line and ground line that are configured to transmit a power source voltage; a low-density source region of the second conductivity type that has an exposed surface that is exposed at the surface of the semiconductor substrate, that is in contact with the high-density source region, and that has a lower impurity concentration than the high-density source region; a high-density drain region of the second conductivity type that is formed along the surface of the semiconductor substrate so as to be separated from the high-density source region and the low-density source region, and that is connected to the other one of the power source line and the ground line; a low-density drain region of the second conductivity type that is formed so as to be separated from the high-density source region and the low-density source region, that has an exposed surface that is exposed at the surface of the semiconductor substrate, that is in contact with the high-density drain region, that has a lower impurity concentration than the high-density drain region, and that extends to a deeper region from the surface of the semiconductor substrate than the low-density source region; a gate insulating film that is formed over the exposed surfaces of the low-density source region and the low-density drain region, as well as a region of the surface of the semiconductor substrate between the exposed surfaces; and a gate electrode that is formed on the gate insulating film, and that is connected to said either one of the power source line and the ground line.

Also, an electrostatic protection element according to the present invention includes: a semiconductor substrate of a first conductivity type; a high-density source region of a second conductivity type that is formed along a surface of the semiconductor substrate, and that is connected to either one of a power source line and ground line that are configured to transmit a power source voltage; a low-density source region of the second conductivity type that has an exposed surface that is exposed at the surface of the semiconductor substrate, that is in contact with the high-density source region, and that has a lower impurity concentration than the high-density source region; a high-density drain region of the second conductivity type that is formed along the surface of the semiconductor substrate so as to be separated from the high-density source region and the low-density source region, and that is connected to the other one of the power source line and the ground line; a low-density drain region of the second conductivity type that is formed so as to be separated from the high-density source region and the low-density source region, that has an exposed surface that is exposed at the surface of the semiconductor substrate, that is in contact with the high-density drain region, and that has a lower impurity concentration than the high-density drain region; a gate insulating film that is formed over the exposed surfaces of the low-density source region and the low-density drain region, as well as a region of the surface of the semiconductor substrate between the exposed surfaces; a gate electrode that is formed on the gate insulating film, and that is connected to said either one of the power source line and the ground line; and a well region of the second conductivity type that is formed on a bottom surface of the low-density drain region, and that has a lower impurity concentration than the high-density drain region.

A semiconductor device according to the present invention includes: a power source line and a ground line that transmit a power source voltage; a semiconductor substrate of a first conductivity type; an internal circuit that is formed on the semiconductor substrate, and that operates using the power source voltage transmitted via the power source line and the ground line; and an electrostatic protection element formed on the semiconductor substrate, wherein the electrostatic protection element includes: a high-density source region of a second conductivity type that is formed along a surface of the semiconductor substrate, and that is connected to either one of a power source line and ground line that are configured to transmit a power source voltage; a low-density source region of the second conductivity type that has an exposed surface that is exposed at the surface of the semiconductor substrate, that is in contact with the high-density source region, and that has a lower impurity concentration than the high-density source region; a high-density drain region of the second conductivity type that is formed along the surface of the semiconductor substrate so as to be separated from the high-density source region and the low-density source region, and that is connected to the other one of the power source line and the ground line; a low-density drain region of the second conductivity type that is formed so as to be separated from the high-density source region and the low-density source region, that has an exposed surface that is exposed at the surface of the semiconductor substrate, that is in contact with the high-density drain region, that has a lower impurity concentration than the high-density drain region, and that extends to a deeper region from the surface of the semiconductor substrate than the low-density source region; a gate insulating film that is formed over the exposed surfaces of the low-density source region and the low-density drain region, as well as a region of the surface of the semiconductor substrate between the exposed surfaces; and a gate electrode that is formed on the gate insulating film, and that is connected to said either one of the power source line and the ground line.

Also, a semiconductor device according to the present invention includes: a power source line and a ground line that transmit a power source voltage; a semiconductor substrate of a first conductivity type; an internal circuit that is formed on the semiconductor substrate, and that operates using the power source voltage transmitted via the power source line and the ground line; and an electrostatic protection element formed on the semiconductor substrate, wherein the electrostatic protection element includes: a high-density source region of a second conductivity type that is formed along a surface of the semiconductor substrate, and that is connected to either one of a power source line and ground line that are configured to transmit a power source voltage; a low-density source region of the second conductivity type that has an exposed surface that is exposed at the surface of the semiconductor substrate, that is in contact with the high-density source region, and that has a lower impurity concentration than the high-density source region; a high-density drain region of the second conductivity type that is formed along the surface of the semiconductor substrate so as to be separated from the high-density source region and the low-density source region, and that is connected to the other one of the power source line and the ground line; a low-density drain region of the second conductivity type that is formed so as to be separated from the high-density source region and the low-density source region, that has an exposed surface that is exposed at the surface of the semiconductor substrate, that is in contact with the high-density drain region, and that has a lower impurity concentration than the high-density drain region; a gate insulating film that is formed over the exposed surfaces of the low-density source region and the low-density drain region, as well as a region of the surface of the semiconductor substrate between the exposed surfaces; a gate electrode that is formed on the gate insulating film, and that is connected to said either one of the power source line and the ground line; and a well region of the second conductivity type that is formed on a bottom surface of the low-density drain region, and that has a lower impurity concentration than the high-density drain region.

In the present invention, when a high voltage due to ESD is applied, bipolar parasitic transistors that are parasitic on the source region and the drain region of the MOS transistor, which is the electrostatic protection element, break down. As a result, the current resulting from ESD flows into the parasitic transistors instead of the internal circuit, thereby preventing electrostatic damage to the internal circuit.

Additionally, in the present invention, the current paths formed by the parasitic transistors through which current resulting from ESD flows are expanded in the depth direction of the semiconductor substrate. Thus, the current density of the current path formed by the parasitic transistor formed directly below the gate insulating film of the MOS transistor is reduced, and in proportion thereto, the threshold of the current at which the Kirk effect occurs during breakdown of the parasitic transistor is increased. Thus, susceptibility to the Kirk effect is reduced, and as a result, a decrease in the hold voltage between the collector and the emitter of the parasitic transistor resulting from the Kirk effect is suppressed, and therefore, after the ESD ends, no large current enters the parasitic transistor even if the power source voltage is applied thereto.

Therefore, according to the present invention, with the use of a single MOS transistor, which is the electrostatic protection element, it is possible not only to prevent damage to the internal circuit due to ESD but also to prevent damage to the transistor itself after the ESD has ended without resulting in an increase in circuit area or insufficient power supply to the internal circuit.

### BRIEF DESCRIPTION OF THE DRAWINGS

FIG. 1 is a circuit diagram that schematically shows a circuit formed in a semiconductor IC chip 100 as a semiconductor device of the present invention.

FIG. 2A is a top view of a transistor 10 as seen from above the semiconductor IC chip 100.

FIG. 2B is a cross-sectional view showing a cross-section of the transistor 10 along the W-W line of FIG. 2A.

FIG. 3 is a drawing in which depictions of parasitic transistors that are parasitic on the transistor 10 are added to the cross-section of the transistor 10.

FIG. 4 is a cross-sectional view showing another cross-section of the transistor 10 along the W-W line of FIG. 2A, wherein the transistor 10 of FIG. 4 has a different configuration from the transistor 10 of FIG. 2B.

### DETAILED DESCRIPTION OF EMBODIMENTS

Embodiments of the present invention will be explained in detail below with reference to the drawings.

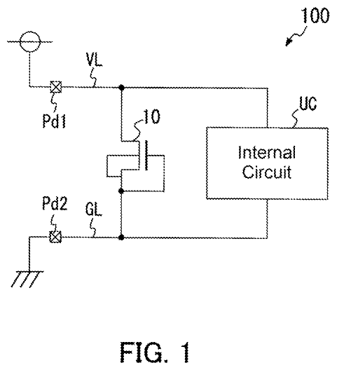

FIG. 1 is a circuit diagram that schematically shows a circuit formed in a semiconductor IC chip 100 as a semiconductor device of the present invention.

The semiconductor IC chip 100 has formed therein an internal circuit UC that performs the primary function, and an n-channel MOS (metal-oxide-semiconductor) transistor 10 as the electrostatic protection element of the present invention. Additionally, the semiconductor IC chip 100 has formed therein pads Pd1 and Pd2 that receive a power source voltage from the outside, and a power source line VL and a ground line GL that transmit the power source voltage received by the pads Pd1 and Pd2. The internal circuit UC operates using the power source voltage transmitted via the power source line VL and the ground line GL.

As shown in FIG. 1, the drain of the transistor 10 is connected to the power source line VL, and the gate and the source thereof are both connected to ground line GL.

Below, the configuration of the transistor 10 will be explained.

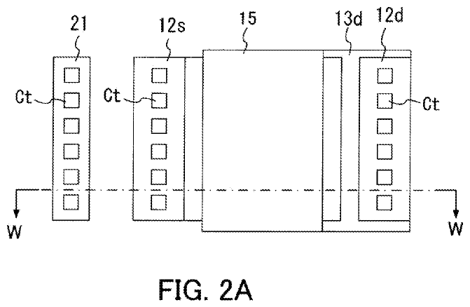

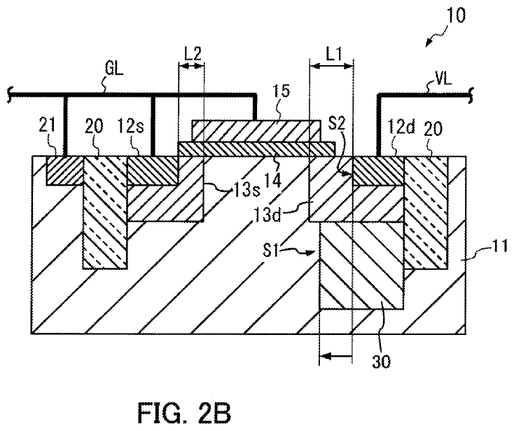

FIG. 2A is a top view of a transistor 10 as seen from above the semiconductor IC chip 100, and FIG. 2B is a cross-sectional view along the W-W line of FIG. 2A.

As shown in FIG. 2B, the transistor 10 is formed on a semiconductor substrate 11 made of a P-type Si (silicon).

At the vicinity of the surface of the semiconductor substrate 11, an N-type high-density source region 12s that functions as the source region of the transistor 10, and an N-type low-density source region 13s with an impurity concentration lower than the high-density source region 12s are formed.

The top surface of the high-density source region 12s is exposed at the surface of the semiconductor substrate 11, and the ground line GL is connected to a contact Ct formed on the top surface.

The low-density source region 13s has an exposed surface that is exposed at the surface of the semiconductor substrate 11, and is connected to the high-density source region 12s so as to cover the side surface and bottom surface of the high-density source region 12s within the semiconductor substrate 11.

Also, at the vicinity of the surface of the semiconductor substrate 11, an N-type high-density drain region 12d that functions as the drain region of the transistor 10, and an N-type low-density drain region 13d with an impurity concentration lower than the high-density drain region 12d are formed.

The top surface of the high-density drain region 12d is exposed at the surface of the semiconductor substrate 11, and the power source line VL is connected to a contact Ct formed on the top surface.

The low-density drain region 13d has an exposed surface that is exposed at the surface of the semiconductor substrate 11, and is connected to the high-density drain region 12d so as to cover the side surface and bottom surface of the high-density drain region 12d within the semiconductor substrate 11.

Also, as shown in FIG. 2B, a gate insulating film 14 (e.g., an oxide film) is formed over the exposed surfaces of the low-density source region 13s and the low-density drain region 13d, as well as the region of the surface of the semiconductor substrate 11 between the exposed surfaces. A gate electrode 15 is formed on the gate insulating film 14. The gate electrode 15 is connected to the ground line GL.

Also, a shallow trench isolation (STI) structure element isolation insulating film 20 is formed so as to surround, in a loop, the entire region in which the high-density source region 12s, the high-density drain region 12d, the low-density source region 13s, and the low-density drain region 13d are formed.

Also, a P-type high-density diffusion layer 21 is formed in a section of the outer periphery of the looped element isolation insulating film 20 in the vicinity of the surface of the semiconductor substrate 11. The high-density diffusion layer 21 is connected to the ground line GL, and the back gate of the transistor 10 has applied thereto a ground potential via the ground line GL and the high-density diffusion layer 21.

Additionally, as shown in FIG. 2B, the bottom surface of the low-density drain region 13d functioning as the drain region in the semiconductor substrate 11 has formed thereon an N-type n-well 30 having a lower impurity concentration than the high-density drain region 12d.

Here, as shown in FIG. 2B, the side surface S1 of the n-well 30 juts further out towards the source region (12s, 13s) than does the side surface S2 of the high-density drain region 12d opposing the high-density source region 12s.

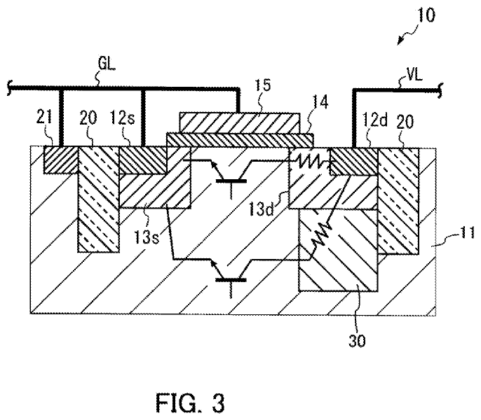

Below, the electrostatic protection operation by the transistor 10 shown in FIGS. 1, 2A, and 2B will be described with reference to FIG. 3.

FIG. 3 is a drawing in which depictions of bipolar parasitic transistors that are parasitic on the drain and source of the transistor 10 are added to the cross-section of the transistor 10.

First, as shown in FIG. 1, when a high voltage is applied between the pads Pd1 and Pd2 due to ESD occurring in the vicinity of the semiconductor IC chip 100, a bipolar parasitic transistor that is parasitic between the drain and source of the MOS transistor 10 breaks down.

Next, as shown in FIG. 3, in the transistor 10, a bipolar parasitic transistor is formed between the low-density source region 13s and the low-density drain region 13d, and a bipolar parasitic transistor is also formed via the n-well 30 between the low-density source region 13s and the low-density drain region 13d.

When the parasitic transistor breaks down as described above, the discharge current resulting from ESD flows from the power source line VL into the ground line GL via the current path constituted of the high-density drain region 12d, the low-density drain region 13d, a region of the semiconductor substrate 11 in the vicinity of the surface, the low-density source region 13s, and the high-density source region 12s, for example. Additionally, the discharge current flows into the ground line GL via the current path constituted of the high-density drain region 12d, the low-density drain region 13d, the n-well 30, a region of the semiconductor substrate 11 away from the surface, the low-density source region 13s, and the high-density source region 12s, for example.

Thus, the current resulting from ESD flows through the current paths formed by the bipolar parasitic transistors shown in FIG. 3 instead of the internal circuit UC, thereby preventing electrostatic damage to the internal circuit UC.

Here, in the transistor 10, the current path resulting from the parasitic transistor breaking down is expanded in the depth direction of the semiconductor substrate 11 due to the n-well 30 formed on the bottom surface of the low-density drain region 13d. Thus, the current density of the current path formed by the parasitic transistor in the region directly below the gate insulating film 14 is reduced. As a result, the threshold of current at which the Kirk effect would occur is increased for the current flowing via the parasitic transistor between the high-density drain region 12d and the high-density source region 12s. Also, compared to a case in which the n-well 30 is not formed on the bottom surface of the low-density drain region 13d, susceptibility to the Kirk effect is reduced, and as a result, a decrease in the hold voltage between the collector and the emitter of the parasitic transistor resulting from the Kirk effect is suppressed.

Thus, after the ESD ends, even if a normal power source voltage is applied to the transistor 10 through the power source line VL and the ground line GL, flow of a large current to the parasitic transistor is prevented. As a result, after the ESD ends, a current based on the power source voltage is supplied to the internal circuit UC without passing through the parasitic transistor, and thus, insufficient power supply to the internal circuit UC is alleviated and damage to the transistor 10 that is the electrostatic protection element is prevented.

Thus, with the use of a single transistor 10 that is the electrostatic protection element, it is possible to prevent damage to the internal circuit due to ESD and to prevent damage to the electrostatic protection element (transistor 10) itself after the ESD has ended without resulting in an increase in circuit area or insufficient power supply to the internal circuit.

Additionally, as shown in FIG. 2B, in the transistor 10, the shortest distance L1 from the boundary between a region of the semiconductor substrate 11 and the low-density drain region 13d to the high-density drain region 12d in the direction along the surface of the semiconductor substrate 11 is set to be greater than the shortest distance L2 from the boundary between the region of the semiconductor substrate 11 and the low-density source region 13s and the high-density source region 12s.

In this case, the greater the distance L1 is, the greater the electrical resistance is within the current paths resulting from the parasitic transistors shown in FIG. 3, and as a result, the voltage threshold at which the Kirk effect would occur is increased, thereby mitigating a decrease in the hold voltage between the collector and the emitter of the parasitic transistor resulting from the Kirk effect. Thus, it is possible to prevent insufficient power supply to the internal circuit UC after the end of ESD and damage to the electrostatic protection element (10) in a more reliable manner.

In the example shown in FIG. 2B, the n-well 30 is provided in order to expand the current path in the depth direction of the semiconductor substrate 11 during breakdown, but the low-density drain region itself may be expanded in the depth direction of the semiconductor substrate 11 without separately forming the n-well 30.

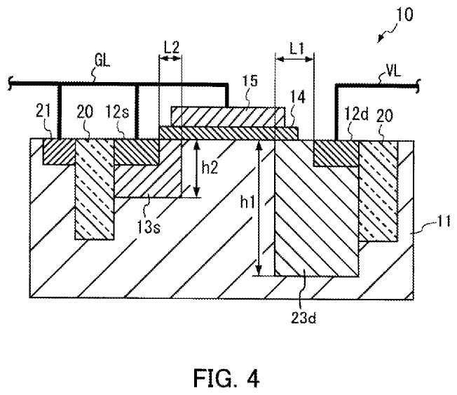

FIG. 4 is a cross-sectional view showing a configuration of the transistor 10 along the W-W line of FIG. 2A conceived of according to this point.

The configuration of FIG. 4 is the same as that of FIG. 2B other than a low-density drain region 23d being used instead of the low-density drain region 13d and the n-well 30. Thus, a configuration of the low-density drain region 23d shown in FIG. 4 will be described below.

Similar to the low-density drain region 13d, the low-density drain region 23d has an exposed surface that is exposed at the surface of the semiconductor substrate 11, and is in contact with the high-density drain region 12d so as to cover the side surface and bottom surface of the high-density drain region 12d within the semiconductor substrate 11.

However, as shown in FIG. 4, a depth h1 from the surface of the semiconductor substrate 11 to the bottom surface of the low-density drain region 23d is greater than a depth h2 from the surface of the semiconductor substrate 11 to the bottom surface of the low-density source region 13s. That is, the low-density drain region 23d extends to a greater depth from the surface of the semiconductor substrate 11 than the low-density source region 13s within the semiconductor substrate 11.

As a result, the current path for when the bipolar parasitic transistor that is parasitic on the MOS transistor 10 breaks down is expanded in the depth direction of the semiconductor substrate 11 as compared to a case in which the depth of the low-density drain region is set to be equal to the depth h2 of the low-density source region 13s. Thus, the current density of the current path formed by the parasitic transistor in the vicinity of the gate insulating film 14 is reduced, and, in proportion thereto, the threshold of the current at which the Kirk effect occurs is increased.

Therefore, compared to a case in which the low-density drain region is equal in depth to the low-density source region 13s, susceptibility to the Kirk effect is reduced, and as a result, a decrease in the hold voltage between the collector and the emitter of the parasitic transistor resulting from the Kirk effect is suppressed.

Thus, after the ESD ends, even if a normal power source voltage is applied to the transistor 10 through the power source line VL and the ground line GL, flow of a large current to the parasitic transistors is prevented.

Therefore, similarly to the configuration shown in FIG. 2B, even with the use of the configuration shown in FIG. 4, with the use of a single transistor 10 that is the electrostatic protection element, it is possible not only to prevent damage to the internal circuit due to ESD but also to prevent damage to the transistor itself after the ESD has ended without resulting in an increase in circuit area or insufficient power supply to the internal circuit.

In the embodiments above, a configuration was described in which a MOS transistor 10 is formed on a P-type conductivity semiconductor substrate 11, but the transistor 10 can similarly be formed on an N-type conductivity semiconductor substrate. Also, the transistor 10 may be formed in an N-type well region formed in the P-type semiconductor substrate or be formed in a P-type well region formed in the N-type semiconductor substrate.

In summary, the transistor 10 functioning as the electrostatic protection element should have the first conductivity type semiconductor substrate described below, a high-density source region and a low-density source region of a second conductivity type, a high-density drain region and a low-density drain region of the second conductivity type, a gate insulating film, and a gate electrode.

That is, the high-density source region (12s) is formed along the surface of the semiconductor substrate (11), and is connected to either one of the power source line (VL) and the ground line (GL), which transmit the power source voltage. The low-density source region (13s) is a region with a lower impurity concentration than the high-density source region, has an exposed surface that is exposed at the surface of the semiconductor substrate, and is in contact with the high-density source region. The high-density drain region (12d) is formed along the surface of the semiconductor substrate so as to be separated from the high-density source region and the low-density source region, and is connected to the other one of the power source line and the ground line, which transmit the power source voltage. The low-density drain region (23d) is formed away from the high-density source region and the low-density source region, has an exposed surface that is exposed at the surface of the semiconductor substrate, is in contact with the high-density drain region, and has a lower impurity concentration than the high-density drain region. The gate insulating film (14) is formed on the surface of the semiconductor substrate, and on the exposed surfaces of the low-density source region and the low-density drain region. The gate electrode (15) is formed on the gate insulating film, and is connected to either one of the power source line and the ground line. The depth (h1) of the low-density drain region (23d) from the surface of the semiconductor substrate is greater than the depth (h2) of the low-density source region (13s) from the surface of the semiconductor substrate. That is, the low-density drain region extends to a greater depth from the surface of the semiconductor substrate than the low-density source region within the semiconductor substrate.

Also, the transistor 10 functioning as the electrostatic protection element may have the first conductivity type semiconductor substrate described below, a high-density source region and a low-density source region of a second conductivity type, a high-density drain region and a low-density drain region of the second conductivity type, a well region of the second conductivity type, a gate insulating film, and a gate electrode.

That is, the high-density source region (12s) is formed along the surface of the semiconductor substrate (11), and is connected to either one of the power source line (VL) and the ground line (GL), which transmit the power source voltage. The low-density source region (13s) is a region with a lower impurity concentration than the high-density source region, has an exposed surface that is exposed at the surface of the semiconductor substrate, and is in contact with the high-density source region. The high-density drain region (12d) is formed along the surface of the semiconductor substrate so as to be separated from the high-density source region and the low-density source region, and is connected to the other one of the power source line and the ground line, which transmit the power source voltage. The low-density drain region (23d) is formed away from the high-density source region and the low-density source region, has an exposed surface that is exposed at the surface of the semiconductor substrate, is in contact with the high-density drain region, and has a lower impurity concentration than the high-density drain region. The well region (30) is formed on the bottom surface of the low-density drain region (13d), and has a lower impurity concentration than the high-density drain region.

What is claimed is:

1. An electrostatic protection element, comprising:
a semiconductor substrate of a first conductivity type;
a high-density source region of a second conductivity type that is formed along a surface of the semiconductor substrate, and that is connected to either one of a power source line and ground line that are configured to transmit a power source voltage;
a low-density source region of the second conductivity type that has an exposed surface that is exposed at the surface of the semiconductor substrate, that is in contact with the high-density source region, and that has a lower impurity concentration than an impurity concentration of the high-density source region;
a high-density drain region of the second conductivity type that is formed along the surface of the semiconductor substrate so as to be separated from the high-density source region and the low-density source region, and that is connected to another one of the power source line and the ground line;
a low-density drain region of the second conductivity type that is formed so as to be separated from the high-density source region and the low-density source region, that has an exposed surface that is exposed at the surface of the semiconductor substrate, that is in contact with the high-density drain region, that has a lower impurity concentration than an impurity concentration of the high-density drain region, and that extends to a deeper region from the surface of the semiconductor substrate than does the low-density source region;
a gate insulating film that is formed over the exposed surfaces of the low-density source region and the low-density drain region, as well as a region of the surface of the semiconductor substrate between the exposed surfaces; and
a gate electrode that is formed on the gate insulating film, and that is connected to said either one of the power source line and the ground line.

2. The electrostatic protection element according to claim 1,
wherein a distance from a boundary between the low-density drain region and a region of the semiconductor substrate to the high-density drain region in a direction along the surface of the semiconductor substrate is greater than a distance from a boundary between the low-density source region and the region of the semiconductor substrate to the high-density source region in the direction along the surface of the semiconductor substrate.

3. An electrostatic protection element, comprising:
a semiconductor substrate of a first conductivity type;
a high-density source region of a second conductivity type that is formed along a surface of the semiconductor substrate, and that is connected to either one of a power source line and ground line that are configured to transmit a power source voltage;
a low-density source region of the second conductivity type that has an exposed surface that is exposed at the surface of the semiconductor substrate, that is in contact with the high-density source region, and that has a lower impurity concentration than an impurity concentration of the high-density source region;
a high-density drain region of the second conductivity type that is formed along the surface of the semiconductor substrate so as to be separated from the high-density source region and the low-density source region, and that is connected to another one of the power source line and the ground line;
a low-density drain region of the second conductivity type that is formed so as to be separated from the high-density source region and the low-density source region, that has an exposed surface that is exposed at the surface of the semiconductor substrate, that is in contact with the high-density drain region, and that has a lower impurity concentration than an impurity concentration of the high-density drain region;
a gate insulating film that is formed over the exposed surfaces of the low-density source region and the low-density drain region, as well as a region of the surface of the semiconductor substrate between the exposed surfaces;
a gate electrode that is formed on the gate insulating film, and that is connected to said either one of the power source line and the ground line; and
a well region of the second conductivity type that is formed on a bottom surface of the low-density drain region, and that has a lower impurity concentration than the impurity concentration of the high-density drain region.

4. The electrostatic protection element according to claim 3,
wherein a distance from a boundary between the low-density drain region and a region of the semiconductor substrate to the high-density drain region in a direction along the surface of the semiconductor substrate is greater than a distance from a boundary between the low-density source region and the region of the semiconductor substrate to the high-density source region in the direction along the surface of the semiconductor substrate.

5. The electrostatic protection element according to claim 3,
wherein one side surface of the well region juts further out towards the high-density source region than does a side surface of the high-density drain region.

6. The electrostatic protection element according to claim 4,
wherein a distance from a boundary between the low-density drain region and a region of the semiconductor substrate to the high-density drain region in a direction along the surface of the semiconductor substrate is greater than a distance from a boundary between the low-density source region and the region of the semiconductor substrate to the high-density source region in the direction along the surface of the semiconductor substrate.

7. A semiconductor device, comprising:
a power source line and a ground line that transmit a power source voltage;
a semiconductor substrate of a first conductivity type;
an internal circuit that is formed on the semiconductor substrate, and that operates using the power source voltage transmitted via the power source line and the ground line; and
an electrostatic protection element formed on the semiconductor substrate,
wherein the electrostatic protection element includes:
a high-density source region of a second conductivity type that is formed along a surface of the semiconductor substrate, and that is connected to either one of a power source line and ground line that are configured to transmit a power source voltage;
a low-density source region of the second conductivity type that has an exposed surface that is exposed at the surface of the semiconductor substrate, that is in contact with the high-density source region, and that has a lower impurity concentration than an impurity concentration of the high-density source region;
a high-density drain region of the second conductivity type that is formed along the surface of the semiconductor substrate so as to be separated from the high-density source region and the low-density source region, and that is connected to another one of the power source line and the ground line;
a low-density drain region of the second conductivity type that is formed so as to be separated from the high-density source region and the low-density source region, that has an exposed surface that is exposed at the surface of the semiconductor substrate, that is in contact with the high-density drain region, that has a lower impurity concentration than an impurity concentration of the high-density drain region, and that extends to a deeper region from the surface of the semiconductor substrate than does the low-density source region;
a gate insulating film that is formed over the exposed surfaces of the low-density source region and the low-density drain region, as well as a region of the surface of the semiconductor substrate between the exposed surfaces; and
a gate electrode that is formed on the gate insulating film, and that is connected to said either one of the power source line and the ground line.

8. A semiconductor device, comprising:
a power source line and a ground line that transmit a power source voltage;
a semiconductor substrate of a first conductivity type;
an internal circuit that is formed on the semiconductor substrate, and that operates using the power source voltage transmitted via the power source line and the ground line; and
an electrostatic protection element formed on the semiconductor substrate,
wherein the electrostatic protection element includes:
a high-density source region of a second conductivity type that is formed along a surface of the semiconductor substrate, and that is connected to either one of a power source line and ground line that are configured to transmit a power source voltage;
a low-density source region of the second conductivity type that has an exposed surface that is exposed at the surface of the semiconductor substrate, that is in contact with the high-density source region, and that has a lower impurity concentration than an impurity concentration of the high-density source region;
a high-density drain region of the second conductivity type that is formed along the surface of the semiconductor substrate so as to be separated from the high-density source region and the low-density source region, and that is connected to another one of the power source line and the ground line;
a low-density drain region of the second conductivity type that is formed so as to be separated from the high-density source region and the low-density source region, that has an exposed surface that is exposed at the surface of the semiconductor substrate, that is in contact with the high-density drain region, and that has a lower impurity concentration than an impurity concentration of the high-density drain region;
a gate insulating film that is formed over the exposed surfaces of the low-density source region and the low-density drain region, as well as a region of the surface of the semiconductor substrate between the exposed surfaces;
a gate electrode that is formed on the gate insulating film, and that is connected to said either one of the power source line and the ground line; and
a well region of the second conductivity type that is formed on a bottom surface of the low-density drain region, and that has a lower impurity concentration than the impurity concentration of the high-density drain region.
